(19) United States
(12) Patent Application Publication
(10) Pub. No.: US 2017/0189995 A1
(43) Pub. Date: Jul. 6, 2017

(54) PRINTING OF 3D STRUCTURES BY LASER-INDUCED FORWARD TRANSFER

(71) Applicant: ORBOTECH LTD., Yavne (IL)

(72) Inventors: Michael Zenou, Hashmonaim (IL); Zvi Kotler, Tel Aviv (IL)

(21) Appl. No.: 15/313,569

(22) PCT Filed: May 20, 2015
(86) PCT No.: PCT/IL2015/000027

§ 371 Date: Nov. 23, 2016

Related U.S. Application Data
(60) Provisional application No. 62/003,135, filed on May 27, 2014.

(51) Int. Cl. B23K 26/34; H01C 17/06; H05K 3/18; H05K 1/16; B23K 26/00; C23C 26/02

(52) U.S. Cl. CPC B23K 26/34; B23K 26/0063; C23C 26/02; H05K 3/18; H05K 1/167; H01C 17/06; B23K 2203/10

(57) ABSTRACT

A method for material deposition includes providing a transparent donor substrate (34) having opposing first and second surfaces and a donor film (36) including a metal formed over the second surface. The donor substrate is positioned in proximity to an acceptor substrate (22), with the second surface facing toward the acceptor substrate, in an atmosphere containing oxygen. Pulses of laser radiation are directed to pass through the first surface of the donor substrate and impinge on the donor film so as to induce ejection from the donor film of droplets (44) of molten material onto the acceptor substrate, forming on the acceptor substrate particles (46) of the metal with an outer layer (54) comprising an oxide of the metal.

### CROSS-REFERENCE TO RELATED APPLICATIONS

This application claims the benefit of U.S. Provisional Patent Application 62/003,135, filed May 27, 2014, which is incorporated herein by reference.

### FIELD OF THE INVENTION

The present invention relates generally to laser-induced material transfer, and particularly to controlling properties of structures created on a substrate by laser-induced forward transfer (LIFT).

### BACKGROUND

In laser direct-write (LDW) techniques, a laser beam is used to create a patterned surface with spatially-resolved three-dimensional structures by controlled material ablation or deposition. Laser-induced forward transfer (LIFT) is an LDW technique that can be applied in depositing micro-patterns on a surface.

In LIFT, laser photons provide the driving force to catapult a small volume of material from a donor film toward an acceptor substrate. Typically, the laser beam interacts with the inner side of the donor film, which is coated onto a non-absorbing carrier substrate. The incident laser beam, in other words, propagates through the transparent carrier before the photons are absorbed by the inner surface of the film. Above a certain energy threshold, material is ejected from the donor film toward the surface of the substrate, which is generally placed, in LIFT systems that are known in the art, either in close proximity to or even in contact with the donor film. The applied laser energy can be varied in order to control the thrust of forward propulsion that is generated within the irradiated film volume. Nagel and Lippert provide a useful survey of the principles and applications of LIFT in micro-fabrication in “Laser-Induced Forward Transfer for the Fabrication of Devices,” published in Nanomaterials: Processing and Characterization with Lasers, Singh et al., eds. (Wiley-VCH Verlag GmbH & Co. KGaA, 2012), pages 255-316.

LIFT techniques using metal donor films have been developed for a variety of applications, such as repair of electrical circuits. For example, PCT International Publication WO 2010/100635, whose disclosure is incorporated herein by reference, describes a system and method of repairing electrical circuits in which a laser is used to pre-treat a conductor repair area of a conductor formed on a circuit substrate. The laser beam is applied to a donor substrate in a manner that causes a portion of the donor substrate to be detached therefrom and to be transferred to a predetermined conductor location.

### SUMMARY

Embodiments of the present invention that are described hereinbelow provide novel techniques for LIFT-based production of 3D metal structures, as well as novel materials and circuit components that may be produced by such techniques.

There is therefore provided, in accordance with an embodiment of the invention, a method for material deposition, which includes providing a transparent donor substrate having opposing first and second surfaces and a donor film including aluminum formed over the second surface. The donor film has a thickness less than 2 μm. The donor substrate is positioned in proximity to an acceptor substrate, with the second surface facing toward the acceptor substrate. Pulses of laser radiation, having a pulse duration between 0.1 ns and 1 ns, are directed to pass through the first surface of the donor substrate and impinge on the donor film so as to induce ejection of droplets of molten material including the aluminum from the donor film onto the acceptor substrate.

Typically, the thickness of the donor film is between 0.3 μm and 1.5 μm.

In some embodiments, the acceptor substrate includes a substrate material selected from a group of materials consisting of thermoset plastics, thermoplastic materials and paper materials.

In a disclosed embodiment, the donor substrate is positioned with the second surface at least 0.1 mm away from the acceptor substrate while the pulses of the laser radiation impinge on the donor film.

In some embodiments, directing the pulses includes setting parameters of the laser radiation so as to produce, on the acceptor substrate, an aggregation of particles including the aluminum and having respective diameters no greater than 5 μm, and possible less than 2 μm. Additionally or alternatively, directing the pulses includes irradiating the donor substrate in an atmosphere containing oxygen, so as to cause an aluminum oxide layer to form on respective outer surfaces of the particles in the aggregation. Setting the parameters may include selecting the parameters so as to adjust an electrical resistivity of the aggregation based at least on a characteristic of the aluminum oxide layer that is determined by the selected parameters.

In one embodiment, directing the pulses includes setting parameters of the laser radiation so that each pulse induces ejection of a single droplet of the molten material.

Additionally or alternatively, the donor substrate has another donor film including another material, in addition to the donor film including the aluminum, formed over the second surface, and the droplets ejected due to the pulses of the laser radiation include a mixture of the aluminum with the other material.

There is also provided, in accordance with an embodiment of the invention, a method for material deposition, which includes providing a transparent donor substrate having opposing first and second surfaces and a donor film including a metal formed over the second surface. The donor substrate is positioned in proximity to an acceptor substrate, with the second surface facing toward the acceptor substrate, in an atmosphere containing oxygen. Pulses of laser radiation are directed to pass through the first surface of the donor substrate and impinge on the donor film so as to induce ejection from the donor film of droplets of molten material onto the acceptor substrate, forming on the acceptor substrate particles of the metal with an outer layer including an oxide of the metal.

In some embodiments, directing the pulses includes scanning the pulses over the donor substrate so as to produce, on the acceptor substrate, an aggregation of the particles. In a disclosed embodiment, directing the radiation includes setting parameters of the pulses so as to adjust an electrical resistivity of the aggregation based at least on a characteristic of the oxide layer that is determined by the parameters. The characteristic of the oxide layer based upon which the electrical resistivity is adjusted typically includes a distribution of openings in the oxide layer between the particles.

In one embodiment, directing the pulses includes setting parameters of the laser radiation so that each pulse induces ejection of a single droplet of the molten material. Alternatively, directing the pulses includes setting parameters of the laser radiation so that each pulse induces ejection of multiple droplets of the molten material.

In the disclosed embodiments, the metal is selected from a group of metals consisting of aluminum, molybdenum, tin, titanium and tungsten and alloys of the metals in the group.

There is additionally provided, in accordance with an embodiment of the invention, a method for material deposition, which includes defining a locus and an electrical resistance of an embedded resistor to be formed on a printed circuit substrate and to contact conductive traces on the printed circuit substrate. A transparent donor substrate is provided, having opposing first and second surfaces and a donor film including a metal formed over the second surface. The donor substrate is positioned in proximity to the printed circuit substrate, with the second surface facing toward the printed circuit substrate. Pulses of laser radiation are directed to pass through the first surface of the donor substrate and impinge on the donor film so as to induce ejection from the donor film of droplets of molten material, which form particles of the metal on the printed circuit substrate, while scanning the pulses so as to fill the locus with an aggregation of the particles that provides the defined resistance between the conductive traces that are in contact with the aggregation.

In some embodiments, directing the pulses includes irradiating the donor substrate in an atmosphere containing oxygen, so as to cause an oxide layer to form on respective outer surfaces of the particles in the aggregation. Typically, irradiating the donor substrate includes setting parameters of irradiation of the donor substrate so as to adjust an electrical resistivity of the aggregation. In one embodiment, setting the parameters includes choosing the parameters so as to regulate a characteristic of the oxide layer upon which the resistivity depends, such as a distribution of openings in the oxide layer between the particles. Additionally or alternatively, setting the parameters includes choosing the parameters so as to regulate a size of the particles.

Typically, setting the parameters includes setting at least one parameter, selected from a group of irradiation parameters consisting of an energy of the pulses, a duration of the pulses, a distance between the donor substrate and the printed circuit substrate, a thickness of the donor film, and a concentration of the oxygen in the atmosphere.

In one embodiment, the donor substrate has another donor film including a dielectric material, in addition to the donor film including the metal, formed over the second surface, and wherein the droplets ejected due to the pulses of the laser radiation and the particles formed on the printed circuit substrate include a mixture of the metal with the dielectric material.

There is further provided, in accordance with an embodiment of the invention, a composition of matter, including an aggregation of particles of a metal with an outer layer including an oxide of the metal. The particles have respective diameters no greater than 5 μm.

In some embodiments, the respective diameters of the particles are less than 2 μm.

In disclosed embodiments, the metal is selected from a group of metals consisting of aluminum, molybdenum, tin, titanium and tungsten and alloys of the metals in the group.

In a disclosed embodiment, the oxide has a thickness that is less than 10 nm and has openings providing electrical contact points between the particles.

There is moreover provided, in accordance with an embodiment of the invention, apparatus for material deposition, including a transparent donor substrate having opposing first and second surfaces and a donor film including aluminum formed over the second surface, the donor film having a thickness less than 2 μm. A positioning assembly is configured to position the donor substrate in proximity to the acceptor substrate, with the second surface facing toward the acceptor substrate. An optical assembly is configured to direct pulses of laser radiation, having a pulse duration between 0.1 ns and 1 ns, to pass through the first surface of the donor substrate and impinge on the donor film so as to induce ejection of droplets of molten material including the aluminum from the donor film onto the acceptor substrate.

There is furthermore provided, in accordance with an embodiment of the invention, apparatus for material deposition, including a transparent donor substrate having opposing first and second surfaces and a donor film including a metal formed over the second surface. A positioning assembly is configured to position the donor substrate in proximity to an acceptor substrate, with the second surface facing toward the acceptor substrate, in an atmosphere containing oxygen. An optical assembly is configured to direct pulses of laser radiation to pass through the first surface of the donor substrate and impinge on the donor film so as to induce ejection from the donor film of droplets of molten material onto the acceptor substrate, forming on the acceptor substrate particles of the metal with an outer layer including an oxide of the metal.

There is also provided, in accordance with an embodiment of the invention, apparatus for material deposition, including a transparent donor substrate having opposing first and second surfaces and a donor film including a metal formed over the second surface. A positioning assembly is configured to position the donor substrate in proximity to a printed circuit substrate, with the second surface facing toward the printed circuit substrate. An optical assembly is configured to direct pulses of laser radiation to pass through the first surface of the donor substrate and impinge on the donor film so as to induce ejection from the donor film of droplets of molten material, which form particles of the metal on the printed circuit substrate, while scanning the pulses so as to fill a predefined locus of an embedded resistor on the printed circuit substrate with an aggregation of the particles that provides a defined electrical resistance between conductive traces on the printed circuit substrate that are in contact with the aggregation.

The present invention will be more fully understood from the following detailed description of the embodiments thereof, taken together with the drawings in which:

### BRIEF DESCRIPTION OF THE DRAWINGS

FIG. 1 is schematic side view of a system for LIFT-based material deposition, in accordance with an embodiment of the present invention;

FIG. 2A is a schematic sectional view of a deposition site on an acceptor substrate, showing LIFT-driven ejection of a metal droplet toward the site in accordance with an embodiment of the present invention;

FIG. 2B is a schematic, pictorial view of a donor film following LIFT-driven ejection of a metal droplet in accordance with an embodiment of the present invention;

FIG. 3 is a schematic, pictorial illustration showing details of a material deposited on a substrate by a LIFT process, in accordance with an embodiment of the invention;

FIG. 4 is a photomicrograph showing particles of aluminum that have been deposited on a substrate by a LIFT process, in accordance with an embodiment of the invention; and

FIG. 5 is a schematic top view of a resistor embedded in a printed circuit, in accordance with an embodiment of the invention.

### DETAILED DESCRIPTION OF EMBODIMENTS

### Overview

Aluminum is an attractive material for use in printed electronics due to the low cost and good conductivity of the metal. The chemical properties of aluminum, however, such as its high reactivity, have been a major obstacle to developing printed circuits and processes that use aluminum conductors. Both conventional printed circuit production and newer, direct-write processes have therefore favored more stable metals, such as copper and gold. A LIFT-based process for circuit repair using mainly copper donor films is described, for example, in Japanese Patent Application 2014-250687, filed Dec. 11, 2014, whose disclosure is incorporated herein by reference.

Some embodiments of the present invention that are described herein provide LIFT techniques that are adapted for use with aluminum donor films and enable stable aluminum structures to be deposited reliably on a wide range of acceptor substrates. Specifically, the inventors have found that very short, energetic laser pulses (typically less than 1 ns), applied to thin aluminum donor films (typically less than 2 μm thick), cause single droplets of molten aluminum to be ejected at high speed toward the donor substrate with precise directionality. By appropriate control of the laser beam parameters, the droplet size and other characteristics can be controlled so that the diameters of the particles of aluminum that are thus created on the acceptor substrate will typically be no larger than 5 μm, and may be less than 2 μm. This fine control of particle size can be maintained even with the donor substrate held relatively far from the acceptor substrate, with a separation between donor and acceptor, for example, of 0.1 mm or more.

The aluminum droplets aggregate on the acceptor substrate to form stable 3D structures. The laser pulses are typically scanned over the donor substrate in order to produce an aggregation of the aluminum particles that fills a predefined locus on the acceptor substrate to a certain desired height. (“Scanning” of the laser pulses in this context, as well as in the claims, typically includes deflection of the laser beam, in order to cover small areas on the acceptor substrate, and may also include translation of the substrate relative to the optical assembly, or vice versa, in order to cover larger loci.) The precision of the disclosed processes makes it possible to create such structures with dimensions of 15 μm or even less on a variety of printed circuit substrates. Furthermore, because the minute droplets cool so quickly upon striking the acceptor substrate, and the process requires no contact with the acceptor substrate, LIFT printing in accordance with embodiments of the present invention can be applied not only to conventional laminated and ceramic acceptor substrates, but also to sensitive substrates, such as thermoplastic, thermoset, organic, and paper-based substrates.

One of the difficulties in working with aluminum in LIFT-based processes is the rapidity with which the molten aluminum oxidizes when exposed to air. Some embodiments overcome this difficulty by operating in a non-oxidizing atmosphere, such as under an argon flush. Other embodiments, however, take advantage of working in an atmosphere containing oxygen in order to create aluminum structures with high, controllable resistivity.

Specifically, the inventors have observed that a thin oxide layer forms during flight of the droplets of molten metal from the donor to the acceptor, and remains on the respective outer surfaces of the metal particles that aggregate on the substrate. This oxide layer creates a certain amount of electrical insulation between neighboring particles. In some embodiments, the parameters of irradiation of the donor, such as the energy and/or duration of the laser pulses, the distance between the donor substrate and the acceptor substrate, the thickness of the donor film, and the concentration of the oxygen in the working atmosphere, are set so as to control the characteristics of oxide layer, and thus adjust the resistivity of the aggregated particles. This technique can be used, inter alia, to create embedded resistors, with a desired, predefined resistance, in contact with conductive traces on a printed circuit substrate.

The LIFT-based metal deposition techniques that are described herein thus create a novel composition of matter, comprising an aggregation of minute particles of a metal, having respective diameters no greater than 5 μm, with an outer layer on the particles comprising an oxide of the metal. In some cases, the respective diameters of the particles are less than 2 μm. The oxide covering the metal particles is typically very thin, with a thickness that is less than 10 nm, and has openings providing electrical contact points between the particles. The thickness of the oxide layer and the number and extent of the openings determine the resistivity of the aggregated material. As noted earlier, these features of the aggregation—and thus its resistivity and other properties—can be controlled by appropriate setting of the irradiation parameters.

Although the embodiments described herein relate mainly to LIFT-based processes using aluminum donor films, the principles of the present invention are similarly applicable to other metals. In particular, the disclosed techniques can be used in depositing structures using other types of metals that have high rates of oxidation, such as molybdenum, titanium, tin and tungsten, inter alia, as well as alloys of aluminum and alloys of these metals. Furthermore, although some of these embodiments relate specifically to interaction of metal in the droplets with ambient oxygen, the principles of the present invention may alternatively be applied using other reactive gases to affect the properties of the particles deposited on the acceptor substrate.

### System Description

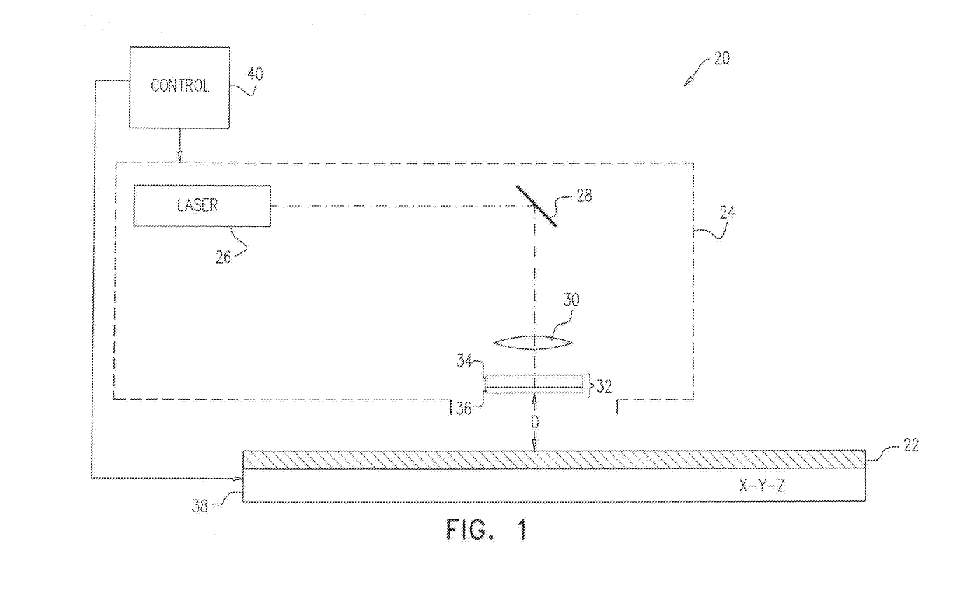

FIG. 1 is a schematic side view of a system 20 for LIFT-based material deposition on an acceptor substrate 22, in accordance with an embodiment of the present invention. System 20 comprises an optical assembly 24, in which a laser 26 emits pulsed radiation, which is focused by suitable optics 30 onto a LIFT donor sheet 32. Laser 26 may comprise, for example, a pulsed Nd:YAG laser with frequency-doubled output, which permits the pulse amplitude to be controlled conveniently by a control unit 40. Typically, for good LIFT deposition results, as described below, the pulse duration is in the range of 0.1 ns to 1 ns. Optics 30 are similarly controllable in order to adjust the size of the focal spot formed by the laser beam on donor 32. A scanner 28, such as a rotating mirror and/or an acousto-optic beam deflector under control of control unit 40, scans the laser beam so as to irradiate different spots on donor sheet 32. Control unit 40 may thus control optical assembly 24 so as to write the donor material over a predefined locus on substrate 22 and to make multiple passes in order to build up the deposited donor material to a desired height.

Substrate 22 typically comprises a dielectric material on which a metallic structure is to be printed, such as a printed electrical circuit. Thus, substrate 22 may comprise a laminated epoxy or ceramic sheet, for example, as are known in the art. Alternatively, system 20 may be used to print conductive traces and other embedded circuit elements (such as resistors, capacitors, and inductors) on substrates of other sorts, such as glass, thermoplastics, thermoset materials, and other polymer and organic materials, and even paper-based materials. Substrate 22 may be either rigid or flexible.

Donor sheet 32 comprises a donor substrate 34 with a donor film 36 formed on the surface that faces toward acceptor substrate 22. Donor substrate 34 comprises a transparent optical material, such as a glass or plastic sheet, while donor film 36 comprises a suitable metallic material, such as aluminum or an aluminum alloy, with a film thickness less than 2 μm. Typically, the thickness of the donor film is between 0.3 μm and 1.5 μm. In some embodiments, multiple donor films are formed over donor substrate 34, including, for example, another film of metal or dielectric material in addition to aluminum film 36. In this case, the droplets ejected from donor sheet 32 due to the pulses of the radiation from laser 26 will comprise a mixture of the aluminum with the other metal or dielectric material.

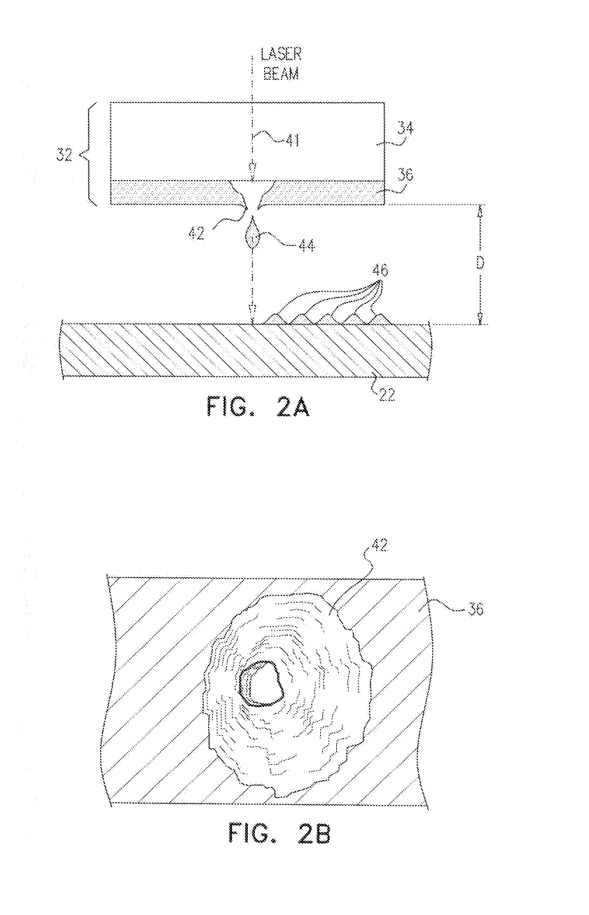

Control unit 40 causes a motion assembly 38 to shift either acceptor substrate 22 or optical assembly 24, or both, in order to align the beam from laser 26 with the locus on the acceptor substrate onto which the material from donor film 36 is to be written. Donor sheet 32 is positioned above the locus in proximity to acceptor substrate 22, at a desired gap width D from the acceptor substrate. Typically, this gap width is at least 0.1 mm, and the inventors have found that gap widths of 0.2 mm or even 0.5 mm or greater can be used, subject to proper selection of the laser beam parameters. Optics 30 focus the laser beam to pass through the outer surface of donor substrate 34 and to impinge on donor film 36, thereby causing droplets of molten metal to be ejected from the film, across the gap and onto acceptor substrate 22. This LIFT process is described in greater detail hereinbelow with reference to FIGS. 2A and 2B.

Typically, control unit 40 comprises a general-purpose computer, with suitable interfaces for controlling and receiving feedback from optical assembly 24, motion assembly 38, and other elements of system 20. System 20 may comprise additional elements (omitted from the figures for the sake of simplicity), such as an operator terminal, which can be used by an operator to set the functions of the system, and an inspection assembly, for monitoring the deposition process. These and other ancillary elements of system 20 will be apparent to those skilled in the art and are omitted from the present description for the sake of simplicity.

### Lift Jetting of Aluminum Droplets

FIG. 2A is a schematic sectional view of a deposition site on substrate 22, showing LIFT-driven ejection of a metal droplet 42 from donor film 36 toward the site, in accordance with an embodiment of the present invention. This figure illustrates the effect of irradiating film 36 with a laser pulse whose duration is comparable to the time required for heat diffusion through the film. Details of this process are described in the above-mentioned Japanese Patent Application 2014-250687, and they will be summarized here only briefly, particularly in relation to aluminum donor films.

Laser 26 directs a laser beam 41 comprising a train of sub-nanosecond laser pulses, toward donor sheet 32. For example, in this embodiment, laser 26 emits pulses of duration 400 ps at a wavelength of 532 nm, with fluence of approximately 0.75 J/cm² at donor film 36. Donor films of thickness between 0.3 μm and 1.5 μm were irradiated in this configuration, at a distance D of about 0.1 mm from acceptor substrate 22.

FIG. 2B is a schematic, pictorial view of donor film 36 following LIFT-driven ejection of droplet 44 in accordance with an embodiment of the present invention. The choice of laser pulse parameters described above gives rise to a “volcano” pattern 42 in the donor film. This “volcano-jetting” regime causes a single droplet 44 to be emitted with high directionality, typically within about 5 mrad of the normal to the film surface. The sizes of the droplets can be controlled by adjusting the energy, pulse duration, and focal spot size of laser beam 41 on donor film 36, as well as the thickness of the donor film. Depending on these parameter settings, the volume of droplets 44 can typically be adjusted within the range of 10 to 100 femtoliter.

An important consequence of the high directionality of drop ejection is that a relatively large gap D can be permitted between donor sheet 32 and acceptor substrate 22 without compromising the printing accuracy. Donor substrate 34 under these conditions can readily be positioned with film 36 at least 0.1 mm away from the acceptor substrate, and can typically be positioned at least 0.2 mm away from the acceptor substrate or even as far as 0.5 mm away while the pulses of the laser radiation impinge on the donor film.

LIFT-driven ejection of droplets takes place only when the laser fluence exceeds a given threshold, which depends on the donor film thickness, the laser pulse duration, and other factors. For short laser pulses (of duration 0.1-1 ns, as described above), single-droplet, “volcano-jetting” ejection will occur over a range of laser fluence values extending from the LIFT threshold up to an upper limit, which is typically about 50% greater than the threshold fluence. Above this upper fluence limit, each laser pulse will tend to induce ejection of many small droplets from the donor film, with nanoscale droplet dimensions. This latter, high-fluence regime is referred to herein as the “sputtering regime.”

Droplets 44 traverse the gap between donor film 36 and substrate 22, and then solidify rapidly as metal particles 46 on the surface of the substrate. The diameters of particles 46 depend on the sizes of droplets 44 that produced them, as well as on the size D of the gap traversed by the particles. Typically, in the volcano-jetting regime, particles 46 have diameters less than 5 μm, and the diameter can be reduced to less than 2 μm by appropriate setting of the LIFT parameters described above.

As molten aluminum droplets 44 pass through the gap between donor and acceptor, the outer surface of the droplets oxidizes rapidly in ambient air or other oxygen-containing atmospheres. An aluminum oxide layer thus forms on the outer surfaces of particles 46. This oxide surface layer causes the resistivity of the particles to increase, relative to bulk aluminum, due to the insulating properties of the oxide. The resistivity increases markedly with the size D of the gap traversed by the droplets, since the size of the gap determines the length of time that the droplets spend in the air. Resistivity also increases with decreasing droplet size, due to the resulting increase of the ratio of the surface area of the corresponding particle 46 to its volume. With large droplets and a small gap size, in ambient air, the inventors were able to create aluminum traces on substrate 22 with resistivity as low as 13.8 μΩ·cm, whereas with small droplets and a large gap, the resistivity increased to as much as 1400 μΩ·cm. Operating laser 26 in the sputtering regime leads to ejection of smaller droplets and thus higher resistivity.

Thus, the resistivity of particles 46 created by system 20 can be readily controlled by varying the irradiation parameters in the system, including the energy and duration of the laser pulses, the gap between donor substrate 34 and acceptor substrate 22, and the thickness and composition of donor film 36. The range of resistivity can be extended and refined still further by controlling the concentration of the oxygen in the atmosphere in the gap: For lower resistivity, the gap may be evacuated or flushed with a non-oxidizing gas, such as argon; alternatively, the concentration of oxygen in the gap may be increased above that in ambient air in order to increase the resistivity.

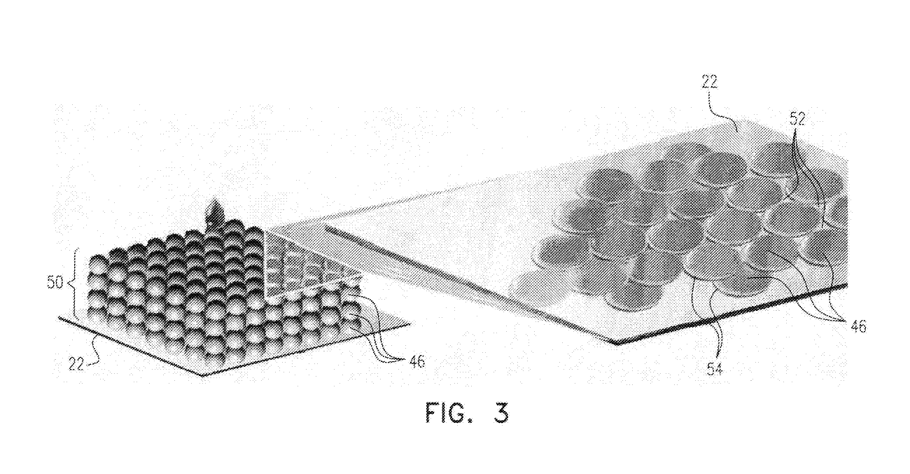

FIG. 3 is a schematic, pictorial view of substrate 22 with a three-dimensional structure 50 deposited on the substrate by a LIFT process, in accordance with an embodiment of the invention. Structure 50 is built up from an aggregation of multiple overlapping layers of particles 46, which are deposited by LIFT jetting in the manner described above. For this purpose, scanner 28 scans laser beam 41 over donor sheet 32, causing pulses of the laser radiation to impinge on donor film 36 at different locations so as to induce ejection of respective droplets 44 of molten material. Donor sheet 32 is also shifted in conjunction with the scanning by scanner 28 so as to fill the target locus on substrate 22 with an aggregation of particles 46 of the desired height, width, and resistivity.

The inset at the right side of FIG. 3 shows details of particles 46, illustrating particularly voids 52 between the particles and an outer layer 54 of aluminum oxide on each of the particles. Voids 52 and particularly layer 54 insulate each particle 46 from its neighbors. In addition to or instead of aluminum, particles 46 may comprise other metals, such as molybdenum, tin, titanium and tungsten, as well as alloys of aluminum and alloys of these latter metals. Additionally or alternatively, the particles may comprise dielectric materials mixed in with the metal by the LIFT process, as explained above. The thickness of outer layer 54 is typically no more than 10 nm and may be as little as 1 nm.

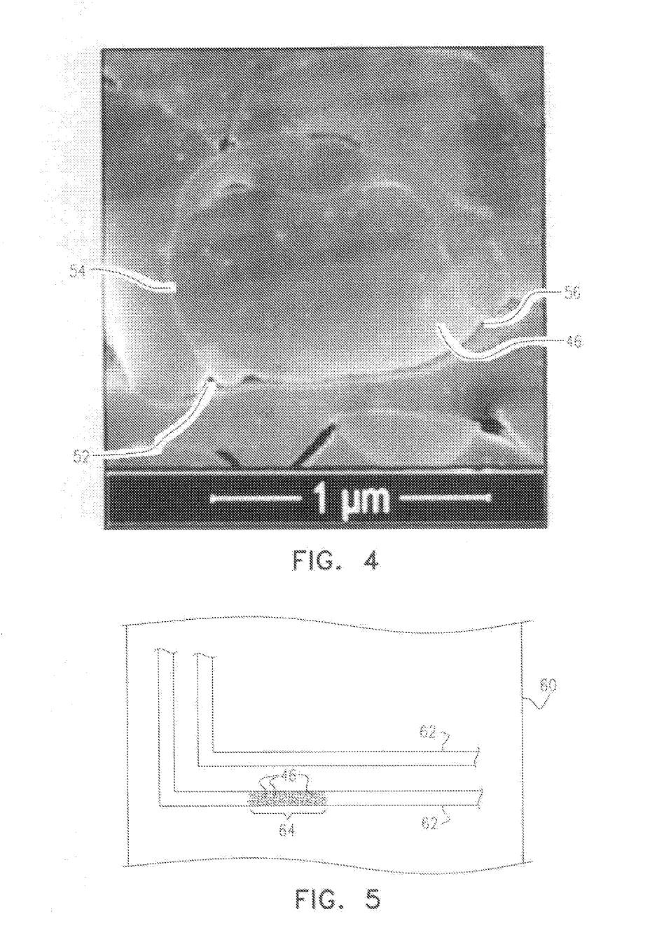

FIG. 4 is a photomicrograph showing particles 46 of aluminum that have been deposited on a substrate by a LIFT process, in accordance with an embodiment of the invention. The insulating shell created by outer layer 54 has an opening 56, where the conductive aluminum inside particle 46 makes contact with the aluminum in the neighboring particle, thus permitting electrical current to flow between the particles. Openings 56 are created at breaks in outer layer 54, which may be caused by the impact of droplets 44 as they land at high speed on structure 50. The distribution of openings 56 in layer 54, such as the sizes and numbers of the openings, also influences the resistivity of the structure.

### Printing of Embedded Resistors

FIG. 5 is a schematic top view of a resistor 64 embedded in a printed circuit 60, in accordance with an embodiment of the invention. Conductive traces 62 are deposited on the circuit substrate either before or after creation of resistor 64 using any suitable process, including both direct-write and conventional photolithographic processes, so that the traces contact the resistor. In one embodiment, the same LIFT process is used to create traces 62 and resistor 64, with process parameters controlled and varied in order to provide the desired conductance characteristics in each part of circuit 60.

The locus and a resistance of resistor 64 are defined as part of the circuit design process, and the irradiation parameters of system 20 are set accordingly, as described above. Donor film 36 for this application comprises aluminum and/or other metals having the appropriate, rapid oxidation rates to creative resistive structures, possibly with the addition of a dielectric material. Optical assembly 24 directs pulses of laser radiation to impinge on donor film 36 so as to induce ejection of droplets of molten material toward the printed circuit substrate, while scanning the pulses so as to fill the locus if resistor 64 with an aggregation of particles 46 that provides the desired resistivity.

This resistivity is adjusted, in combination with the length, width, and height of resistor 64, to provide the predefined resistance between conductive traces 62 that are in contact with the aggregation of particles. The process is performed in an atmosphere containing oxygen, so as to cause an oxide layer to form on the outer surfaces of the particles in the aggregation and thus engender the desired resistivity, as described above. The resistance across resistor 64 may be measured during the LIFT process, and the process parameters and/or dimensions of the printed resistor (such as its height) may be controlled so that the process achieves the exact target resistance that is required by the circuit design.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1-10. (canceled)

11. A method for material deposition, comprising:
providing a transparent donor substrate having opposing first and second surfaces and a donor film comprising a metal formed over the second surface;
positioning the donor substrate in proximity to an acceptor substrate, with the second surface facing toward the acceptor substrate, in an atmosphere containing oxygen; and
directing pulses of laser radiation to pass through the first surface of the donor substrate and impinge on the donor film so as to induce ejection from the donor film of droplets of molten material onto the acceptor substrate, forming on the acceptor substrate particles of the metal with an outer layer comprising an oxide of the metal.

12. The method according to claim 11, wherein directing the pulses comprises scanning the pulses over the donor substrate so as to produce, on the acceptor substrate, an aggregation of the particles.

13. The method according to claim 12, wherein directing the pulses comprises setting parameters of the pulses so that the particles of the metal in the aggregation have respective diameters no greater than 5 μm.

14. The method according to claim 12, wherein directing the radiation comprises setting parameters of the pulses so as to adjust an electrical resistivity of the aggregation based at least on a characteristic of the oxide layer that is determined by the parameters.

15. The method according to claim 14, wherein the characteristic of the oxide layer based upon which the electrical resistivity is adjusted comprises a distribution of openings in the oxide layer between the particles.

16. The method according to claim 11, wherein directing the pulses comprises setting parameters of the laser radiation so that each pulse induces ejection of a single droplet of the molten material.

17. The method according to claim 11, wherein directing the pulses comprises setting parameters of the laser radiation so that each pulse induces ejection of multiple droplets of the molten material.

18. The method according to claim 11, wherein the metal is selected from a group of metals consisting of aluminum, molybdenum, tin, titanium and tungsten and alloys of the metals in the group.

19. A method for material deposition, comprising:
defining a locus and an electrical resistance of an embedded resistor to be formed on a printed circuit substrate and to contact conductive traces on the printed circuit substrate;
providing a transparent donor substrate having opposing first and second surfaces and a donor film comprising a metal formed over the second surface;
positioning the donor substrate in proximity to the printed circuit substrate, with the second surface facing toward the printed circuit substrate; and
directing pulses of laser radiation to pass through the first surface of the donor substrate and impinge on the donor film so as to induce ejection from the donor film of droplets of molten material, which form particles of the metal on the printed circuit substrate, while scanning the pulses so as to fill the locus with an aggregation of the particles that provides the defined resistance between the conductive traces that are in contact with the aggregation.

20. The method according to claim 19, wherein directing the pulses comprises irradiating the donor substrate in an atmosphere containing oxygen, so as to cause an oxide layer to form on respective outer surfaces of the particles in the aggregation.

21. The method according to claim 20, wherein irradiating the donor substrate comprises setting parameters of irradiation of the donor substrate so as to adjust an electrical resistivity of the aggregation.

22. The method according to claim 21, wherein setting the parameters comprises choosing the parameters so as to regulate a characteristic of the oxide layer upon which the resistivity depends.

23. The method according to claim 22, wherein the regulated characteristic of the oxide layer, upon which the resistivity depends, comprises a distribution of openings in the oxide layer between the particles.

24. The method according to claim 21, wherein setting the parameters comprises choosing the parameters so as to regulate a size of the particles.

25. The method according to claim 21, wherein setting the parameters comprises setting at least one parameter, selected from a group of irradiation parameters consisting of an energy of the pulses, a duration of the pulses, a distance between the donor substrate and the printed circuit substrate, a thickness of the donor film, and a concentration of the oxygen in the atmosphere.

26. The method according to claim 19, wherein directing the pulses comprises setting parameters of the pulses so that the particles of the metal in the aggregation have respective diameters no greater than 5 μm.

27. The method according to claim 19, wherein the donor substrate has another donor film comprising a dielectric material, in addition to the donor film comprising the metal, formed over the second surface, and wherein the droplets ejected due to the pulses of the laser radiation and the particles formed on the printed circuit substrate comprise a mixture of the metal with the dielectric material.

28. A composition of matter, comprising an aggregation of particles of a metal with an outer layer comprising an oxide of the metal, the particles having respective diameters no greater than 5 μm.

29. The composition of matter according to claim 28, wherein the respective diameters of the particles are less than 2 μm.

30. The composition of matter according to claim 28, wherein the metal is selected from a group of metals consisting of aluminum, molybdenum, tin, titanium and tungsten and alloys of the metals in the group.

31. The composition of matter according to claim 28, wherein the oxide has a thickness that is less than 10 nm and has openings providing electrical contact points between the particles.

32-41. (canceled)

42. Apparatus for material deposition, comprising:
a transparent donor substrate having opposing first and second surfaces and a donor film comprising a metal formed over the second surface;
a positioning assembly, which is configured to position the donor substrate in proximity to an acceptor substrate, with the second surface facing toward the acceptor substrate, in an atmosphere containing oxygen; and
an optical assembly, which is configured to direct pulses of laser radiation to pass through the first surface of the donor substrate and impinge on the donor film so as to induce ejection from the donor film of droplets of molten material onto the acceptor substrate, forming on the acceptor substrate particles of the metal with an outer layer comprising an oxide of the metal.

43. The apparatus according to claim 42, wherein directing the pulses comprises scanning the pulses over the donor substrate so as to produce, on the acceptor substrate, an aggregation of the particles.

44. The apparatus according to claim 43, wherein the optical assembly is configured to set parameters of the pulses so that the particles of the metal in the aggregation have respective diameters no greater than 5 μm.

45. The apparatus according to claim 43, wherein the optical assembly is configured to set parameters of the pulses so as to adjust a resistivity of the aggregation based at least on a characteristic of the oxide layer that is determined by the parameters.

46. The apparatus according to claim 45, wherein the characteristic of the oxide layer based upon which the electrical resistivity is adjusted comprises a distribution of openings in the oxide layer between the particles.

47. The apparatus according to claim 42, wherein the optical assembly is configured to set parameters of the laser radiation so that each pulse induces ejection of a single droplet of the molten material.

48. The apparatus according to claim 42, wherein the optical assembly is configured to set parameters of the laser radiation so that each pulse induces ejection of multiple droplets of the molten material.

49. The apparatus according to claim 42, wherein the metal is selected from a group of metals consisting of aluminum, molybdenum, tin, titanium and tungsten and alloys of the metals in the group.

50-58. (canceled)
